(19) United States
(12) Patent Application Publication
(10) Pub. No.: US 2014/0097515 A1
(43) Pub. Date: Apr. 10, 2014

(54) COMPOUND SEMICONDUCTOR INTEGRATED CIRCUIT WITH THREE-DIMENSIONALLY FORMED COMPONENTS

(71) Applicant: WIN Semiconductors Corp., Tao Yuan Shien (TW)

(72) Inventor: Shinichiro TAKATANI, Tao Yuan Shien (TW)

(73) Assignee: WIN Semiconductors Corp., Tao Yuan Shien (TW)

(21) Appl. No.: 14/103,918

(22) Filed: Dec. 12, 2013

Related U.S. Application Data
(62) Division of application No. 13/311,619, filed on Dec. 6, 2011.

(51) Int. Cl. H01L 27/06

(52) U.S. Cl. CPC H01L 27/0688
USPC 257/531

(57) ABSTRACT

A compound semiconductor integrated circuit with three-dimensionally formed components, such as three-dimensionally formed bond pads or inductors, positioned above an electronic device. The dielectric layer inserted between the electronic device and the bond pads or inductors thereon has a thickness between 10 to 30 microns, so that it can effectively mitigate the effect of the structure on the device performance. A SiN protection layer can be disposed to cover the electronic devices to prevent contamination from the bond pad or inductor material to the electronic device, and therefore the lower cost copper can be used as the bond pad and inductor material. The three-dimensional bond pad can be used in wire bonding or bump bonding technology.

### BACKGROUND OF THE INVENTION

1. Field of the invention

The present invention relates to a compound semiconductor integrated circuit with three-dimensionally formed components, particularly to a compound semiconductor integrated circuit with bond pads or inductors positioned on top of electronic devices with a dielectric layer inserted in between.

2. Background

As the development of mobile communication, the demand of monolithic microwave integrated circuits (MMICs) of high integration, high performance, and simple manufacturing process is growing as well. Conventionally, components of a MMIC, such as transistors, capacitors, resistors, inductors, input/output pads for signals and their interconnections are positioned in a two-dimensional manner. However, bond pads usually occupy a large surface area, which would significantly reduce the device integration and increase the die size. In order to save the surface area occupied by bond pads, a three-dimensional MMIC technology has been developed. This was usually achieved by positioning the bond pads on top of the electronic devices and inserting a dielectric layer between the bond pads and the electronic devices for electrical isolation. Via holes can be fabricated in the dielectric layer in order to provide electrical connections between the bond pads and the electrodes of the electronic devices. In this way, the MMIC components are positioned in a three-dimensional manner, which utilizes the vertical space instead of the surface area, and therefore has the benefit of die size reduction,

However, such a three-dimensional arrangement of MMIC components may induce capacitance between the metal bond pads and the metal layers of the electronic devices. The induced capacitance may couple to the RF signals in a MMIC, and hence degrade the performance of electronic devices and the reliability of the integrated circuit.

Apart from bond pads, inductors are also components of large footprints in MMICs. In order to save the surface area occupied by inductors, it is also possible to dispose inductors on electronic devices in a three-dimensional manner with a dielectric layer inserted in between. However, for an inductor placing on top of the electronic devices, the RF signal coupling will also impact the device performance considerably, particularly leading to a degradation in the Q-factor. It is therefore an important subject to mitigate the impacts of coupling capacitance and other RF signal coupling on the device performance when the IC components are arranged in a three-dimensional manner.

Conventionally, gold is the most commonly used material for the bond pads and device interconnections in the GaAs-based MMIC technology. Recently, copper is more preferred, because of its lower resistivity and manufacture costs. However, a drawback of using copper as the bond pad metal is that Cu atoms can easily diffuse into the dielectric layer, which may even reach the active area of the electronic devices, leading to device damages. In particular, Cu is known as a carrier killer for compound semiconductors such as GaAs. Once Cu atoms reach the compound semiconductor region in the electronic devices, they diffuse into the semiconductor and largely change its electrical characteristics. To take the advantages of copper bond pads, it is necessary to design a reliable protection layer in the three-dimensionally arranged components for preventing the device degradation or even damage caused by the Cu atom diffusions.

### SUMMARY OF THE INVENTION

The main object of the present invention is to provide a compound semiconductor integrated circuit with three-dimensionally formed components, of which bond pads are positioned on top of the electronic devices with a dielectric layer inserted in between, which provides sufficient isolation between the electronic devices and the bond pads thereon, such that the impacts of the coupling capacitance on the device performance can be mitigated while reducing the die size.

To reach the objects stated above, the present invention provides a compound semiconductor integrated circuit comprising sequentially at least an electronic device, a first dielectric layer, and a bond pad, wherein the first dielectric layer is inserted between the bond pad and the electronic device.

Another object of the present invention is to provide a compound semiconductor integrated circuit with three-dimensionally formed components, of which inductors are positioned on top of the electronic devices with a dielectric layer inserted in between, which provides sufficient isolation between the electronic devices and the inductors thereon, such that the loss characterized as the degradation of Q-factor can be mitigated.

To reach the objects stated above, the present invention provides a compound semiconductor integrated circuit comprising sequentially at least an electronic device, a first dielectric layer, and an inductor, wherein the first dielectric layer is inserted between the inductor and the electronic device.

It is still an object of the present invention to provide a compound semiconductor integrated circuit with three-dimensionally formed components, of which the bond pads or inductors are made of copper and are positioned on top of the electronic devices with a dielectric layer inserted in between, wherein a SiN protection layer is further inserted above the electronic devices to prevent contaminations diffusing from the copper bond pad.

In an embodiment, the first dielectric layer is formed preferably of PBO (Polybenzoxazole) dielectric material.

In an embodiment, the electronic devices can be a HEMT (high electron mobility transistor), a HBT (heterojunction bipolar transistor), a diode, a TFR (thin film resistor), a metal insulator metal (MIM) capacitor, or stacked MIM capacitors.

In an embodiment, the bond pad is formed preferably of copper.

In an embodiment, the preferable thickness of the first dielectric layer is in a range of 10 to 30 microns.

In an embodiment, a metal pillar formed preferably of copper is further formed on the bond pad for bump bonding.

In an embodiment, the inductor is formed preferably of copper.

The present invention will be understood more fully by reference to the detailed description of the drawings and the preferred embodiments below.

### BRIEF DESCRIPTION OF DRAWINGS

FIG. 1 is a schematic showing the cross-sectional view of a compound semiconductor integrated circuit with three-dimensional bond pads according to the present invention

FIG. 2 is a schematic showing the cross-sectional view of another structure of a compound semiconductor integrated circuit with three-dimensional bond pads and metal pillar according to the present invention.

FIGS. 3A, 3B, and 3C are schematics showing top view and cross-sectional side views of a compound semiconductor integrated circuit with three-dimensional inductor.

FIG. 4 is a graph illustrating the simulation results of isolation of a bond pad positioned above HEMTs versus the input power.

FIG. 5 is a graph illustrating the simulation results of isolation of a bond pad positioned above HEMTs versus the thickness of the inserted dielectric layer.

FIG. 6 is a graph illustrating the simulated Q-factor of an inductor placed above a MIM capacitor, a stacked MIM capacitor, and a HBT power cell, a TFR (thin film resistor), and comparing with the result of an inductor placed at a position without any component underneath versus the thickness of the inserted dielectric layer.

FIG. 7A and 7B are schematics showing the top view of the layout of SPDT switches before and after the three RF pads are placed over HEMTs respectively.

### DETAILED DESCRIPTION OF THE INVENTION

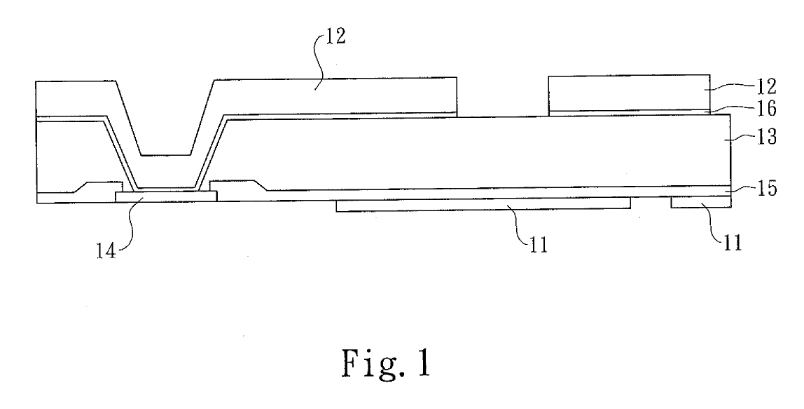

FIG. 1 is a schematic showing the cross-sectional view of a compound semiconductor integrated circuit according to the present invention, which generally comprises at least one electronic device 11, a bond pad 12 positioned above the electronic device 11, and a first dielectric layer 13 inserted in between for electrical isolation. The electronic device 11 is formed on a compound semiconductor substrate, preferentially a semi-insulating GaAs substrate. The electronic device 11 can be a high electron mobility transistor (HEMT), a heterojunction bipolar transistor (HBT), a thin film resistor (TFR), a diode, a metal-insulator-metal (MIM) capacitor, or a stacked MIM capacitor, etc.

The thickness of the first dielectric layer 13 inserted between the bond pad 12 and electronic device 11 is in the range of 10 to 30 microns. The thickness in this range can effectively reduced the capacitance between the electronic device 11 and the bond pad 12 thereon, and thereby mitigating the impact of the coupling capacitor on the device performance.

To have a qualitative estimation, we consider the bond pad 12, the dielectric layer 13 and the conductive layer of the underlying devices as a parallel-plate capacitor, of which the capacitance C_{pad} is given by

C_{pad}=εS/d, Eq. (1)

where S is the area of the capacitor (or the bond pad for the extreme case), d is the thickness of the dielectric layer 13, and ε is the dielectric constant of the dielectric material. For a typical bond pad area of about S=80 μm×80 μm, and ε=3.0 for typical dielectric materials (such as BCB and PBO), the resulting C_{pad} values for different dielectric thicknesses are listed in Table 1:

TABLE 1

| d (μm) | C_{pad} (fF) |
|---|---|
| 3 | 56.7 |
| 5 | 34.0 |
| 7 | 24.3 |
| 10 | 17.0 |
| 15 | 11.3 |
| 20 | 8.5 |
| 25 | 6.8 |
| 30 | 5.7 |

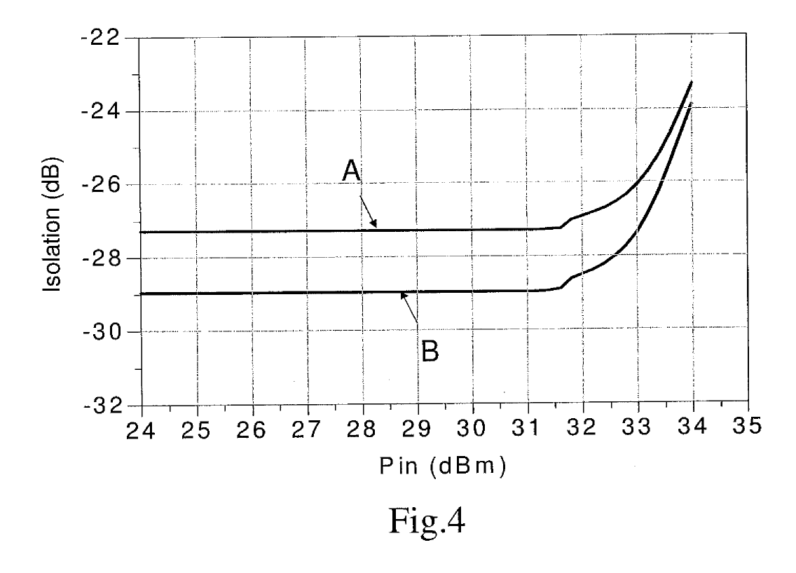

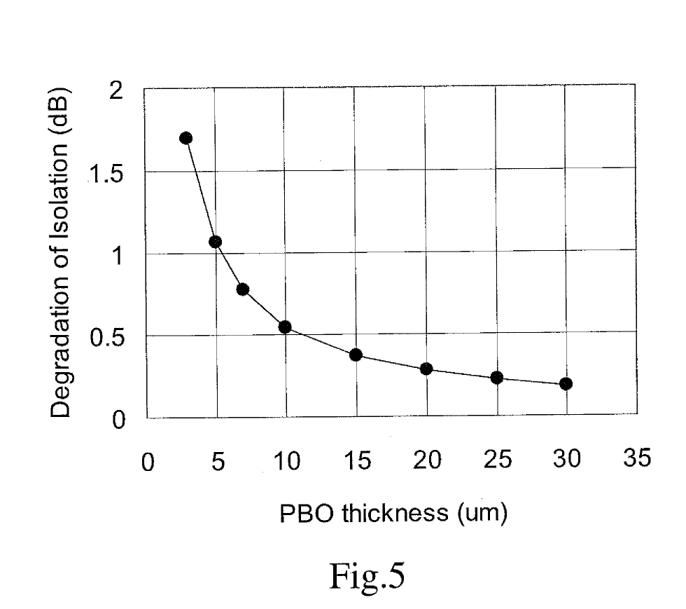

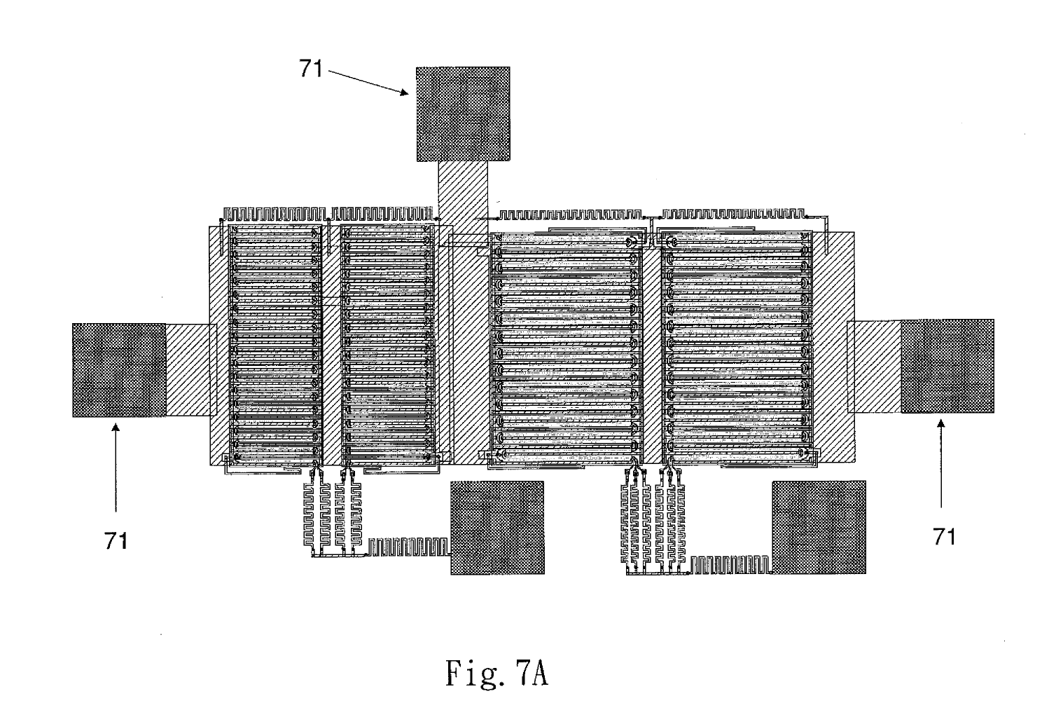

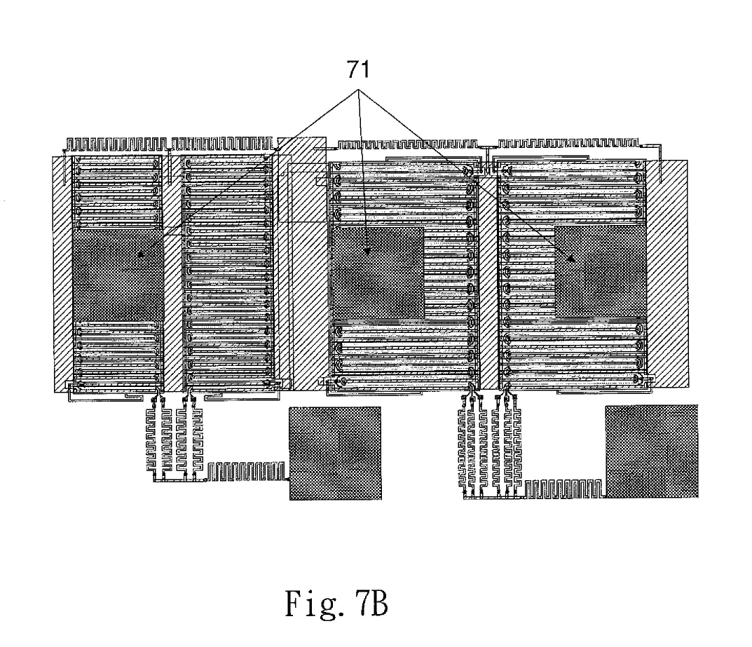

Now we consider the induced capacitance in SPDT switches, for example. FIG. 7A and 7B are schematics showing the top view of the layout of SPDT switches according to the previous technology and the present invention respectively. The device on the left side is composed of two series-connected dual-gate HEMTs with the gate width of 2.625 mm. The device on the right side is composed of two series-connected triple-gate HEMTs with the gate width of 3.375 mm. In a conventional circuit, the RF pads 71 are placed at the periphery of HEMTs, as shown in FIG. 7A. In a circuit with three-dimensional components according to the present invention, the three RF pads 71 are placed over HEMTs, as shown in FIG. 7B. Circuit simulation is conducted for the case in which the left device is turned on and the right device is turned off. The control voltages to turn on and off the devices are 0.5V and −3V, respectively. The RF performance is simulated for the fundamental signal frequency at 0.9 GHz. The simulation for the worst case considering a bond-pad capacitor inserted between the source and the drain of HEMTs shows that the impacts of C_{pad} on the insertion loss and the nonlinearity are insignificant. However, the switch isolation is significantly degraded by 1.7 dB for a dielectric layer thickness of d=3 μm (C_{pad}=56.7 fF), as compared with that without bond pad thereon. The simulated results are shown in FIG. 4, wherein line A is the result for a dielectric layer thickness of d=3 μm with the bond pads thereon, comparing to the result without the bond pads (line B). Simulations further indicate that degradation in the switch isolation decreases monotonically with the dielectric layer thickness, as shown in FIG. 5. The degradation becomes less than 0.6 dB when the dielectric layer thickness is thicker than 10 μm and even less than 0.3 dB when the thickness is thicker than 20 μm.

The first dielectric layer 13 can be a spin-on dielectric formed via conventional spin-coating and curing processes on the electronic device 11. In order to coat a dielectric layer with a thickness up to 10-30 μμm, the dielectric material is preferentially a PBO (polybenzoxazole) layer, of which the thickness could be thicker than 10 μm after curing when the spin speed was reduced to below 1500 rpm. In addition, the PBO dielectric is a photosensitive material, which can act as a positive-tone photoresist layer for the fabrication of various three-dimensional structures on the electronic devices. For examples, trenches or via holes structures can be formed on the device by using the standard photolithography processes, such as exposure, development, and curing.

The bond pad 12 can be electrically connected to a metal contact pad 14 in the vicinity of the electronic device 11 through a via hole 10 in the first dielectric layer 13. The metal contact pad may be further connected to one of the electrodes of the electric device 11, or some other electronic devices disposed in the vicinity.

Gold is usually used in integrated circuits, while copper is more preferred for its low cost. However, copper can easily diffuse into other material, which causes contamination of the electronic devices and the substrate. According to the present invention, as shown in FIG. 1, a SiN protection layer 15 is further inserted between the electronic device 11 and the first dielectric layer 13. The SiN protection layer 15 can act as a diffusion barrier for Cu atoms, and thereby preventing the diffusion of contaminations into the electronic devices. The SiN protection layer 15 is preferably formed over the topmost Au metal layer forming the contact pad 14, as shown in FIG. 1. In the manufacturing process according to the present invention, copper bond pads are formed during the back-end process after all of the front-end processes up to the SiN protection layer are finished. It avoids the contamination of the front-end process with copper and preserves the chip reliability. A seed metal layer 16 can be used for copper plating. The seed metal layer is form preferably of Pd, Cu/Ti or Cu/TiW. The seed metal layer also acts as a diffusion barrier for Cu atoms.

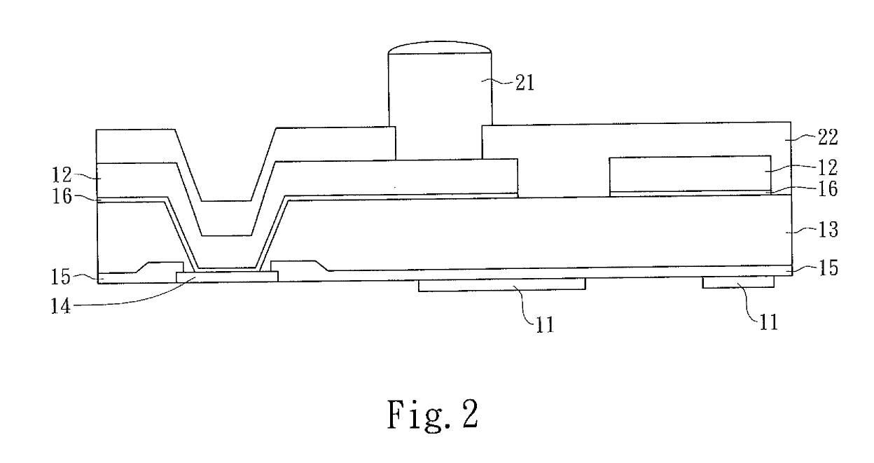

FIG. 2 is a cross-sectional view showing the structure of another embodiment of the present invention including a metal pillar 21 formed on the bond pad 12. A second dielectric layer 22 may be provided to cover the bond pad 12 for surface passivation. The metal pillar 21 is formed preferably of copper. The second dielectric layer 22 is formed preferably of PBO dielectric material. The structure of the embodiment with metal pillars may be used for bump bonding in the flip-chip packaging technology.

Apart from three-dimensionally disposed bond pads, inductors can also be disposed on electronic devices in a three-dimensional manner with a dielectric layer inserted in between. The electronic device can be a HEMT, a HBT, a HBT power cell, a TFR, a diode, a MIM capacitor, or a stacked MIM capacitor, etc.

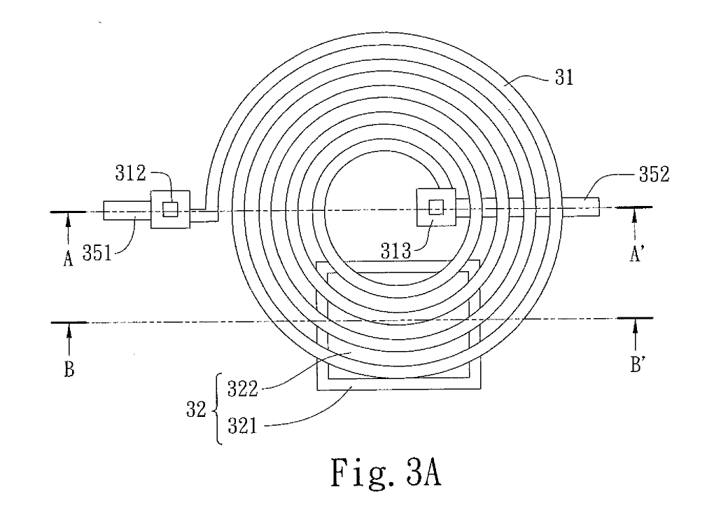

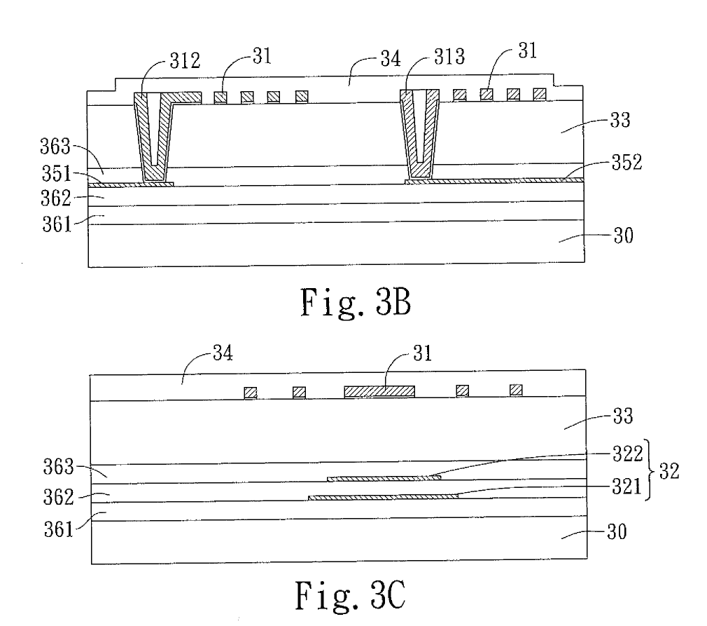

FIG. 3A is a top view of an embodiment, which is a compound semiconductor integrated circuit with three-dimensionally arranged components formed on a GaAs substrate 30, comprising an inductor 31 disposed above a MIM capacitor 32. FIG. 3B is a cross-sectional view along AA′ line in FIG. 3A. The inductor 31 is formed on a first dielectric layer 33. A second dielectric layer 34 is covering on the inductor 31 for surface passivation. The inductor 31 further comprises two contact regions 312 and 313 at the ends of the inductor 31. The two contact regions 312 and 313 further contact with connecting metal layers 351 and 352 disposed underneath the first dielectric layer 33 through via holes 330. The connecting metal layers 351 and 352 can be further connected to other electronic devices (not shown in FIG. 3) for specific applications. FIG. 3C is a cross-sectional view along BB′ line through the MIM capacitor 32 shown in FIG. 3A. The MIM capacitor 32 is formed underneath the inductor 31 and the first dielectric layer 33. The MIM capacitor 32 generally comprises a first metal layer 321 and a second metal_layer 322. In order to provide electrical isolations, a first SiN layer 361 is formed on the GaAs substrate 30. The first metal layer 321 is formed on the first SiN layer 361 and covered by a second SiN layer 362. The second metal layer 322 is then formed on the second SiN layer 362 and finally capped with a SiN protection layer 363.

The first dielectric layer 33 and the second dielectric layer 34 can be a spin-on dielectric formed via conventional spin-coating and curing processes. The spin-on dielectric is preferentially a PBO (polybenzoxazole) layer, of which the thickness could be thicker than 10 μm after curing when the spin speed was carefully controlled.

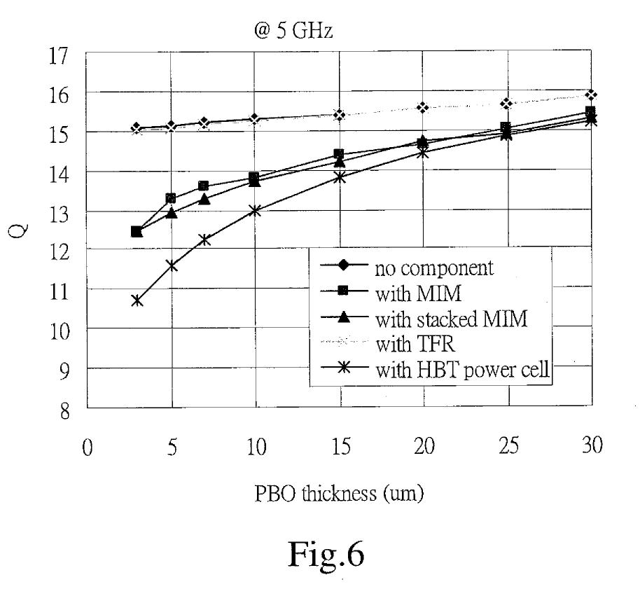

The thickness of the first dielectric layer inserted between the inductor and the electronic device underneath can affect the Q factor of the integrated circuit. FIG. 6 shows the simulated Q values of an inductor placed above a MIM capacitor, a stacked MIM capacitor, and a HBT power cell, a TFR (thin film resistor), and comparing with the result of an inductor placed at a position without any component underneath. It can be seen that the Q factor is degraded as the thickness of the PBO dielectric layer is decreased. The degradation is tolerable when the PBO dielectric layer with a thickness over 10 microns. An optimal dielectric thickness between an inductor and electronic devices is therefore an important consideration for a three-dimensionally arranged MMIC.

As described above, the present invention indeed achieve the expected goal, that is, to provide a compound semiconductor integrated circuit with three-dimensionally formed components. The function of the dielectric layer in the integrated circuit of the present invention is improved, so that the effect of the bond pads structure to the performance of electronic devices can be decreased, while reducing the size of the integrated circuit chip.

Although the present invention has been illustrated and described with respect to exemplary embodiment thereof, it should be understood by those skilled in the art that the foregoing and various other changes, omissions and additions may be made therein and thereto, without departing from the spirit and scope of the present invention.

1. A compound semiconductor integrated circuit, comprising:
an electronic device;
an inductor positioned above said electronic device;
a first dielectric layer inserted between said inductor and said electronic device;
a via hole formed in said first dielectric layer for electrical connection; and
a metal layer formed below said via hole.

2. The compound semiconductor integrated circuit of claim 1, wherein said first dielectric layer has a thickness in a range of 10 to 30 microns.

3. The compound semiconductor integrated circuit of claim 1, wherein said first dielectric layer is formed of PBO (Polybenzoxazole) dielectric material.

4. The compound semiconductor integrated circuit of claim 1, wherein said electronic device further comprising at least one electrode.

5. The compound semiconductor integrated circuit of claim 4, wherein said electrode of said electronic device further comprises a contact region for device interconnections.

6. The compound semiconductor integrated circuit of claim 1, wherein said electronic device with at least one electrode is a HEMT (high electron mobility transistor), a HBT (heterojunction bipolar transistor), a TFR (thin film resistor), a diode, a metal insulator metal (MIM) capacitor, or a stacked MIM capacitor.

7. The compound semiconductor integrated circuit of claim 1, wherein said inductor is formed of copper.

8. The compound semiconductor integrated circuit of claim 1, further comprising a protection layer inserted between said first dielectric layer and said electronic device.

9. The compound semiconductor integrated circuit of claim 8, wherein said protection layer is formed of SiN.

10. The compound semiconductor integrated circuit of claim 8, wherein said protection layer is disposed at least partly over said metal layer.

11. The compound semiconductor integrated circuit of claim 10, wherein said protection layer is formed of SiN.

12. The compound semiconductor integrated circuit of claim 1, further comprising a seed metal layer inserted between said first dielectric layer and said inductor.

13. The compound semiconductor integrated circuit of claim 12, wherein said seed metal layer is formed of Pd, Cu/Ti, or Cu/TiW.

14. The compound semiconductor integrated circuit of claim 1, wherein the said inductor is disposed into a spiral shape.

15. The compound semiconductor integrated circuit of claim 1, further comprising a second dielectric layer covering on said inductor for passivation.

16. The compound semiconductor integrated circuit of claim 15, wherein said second dielectric layer is formed of PBO (Polybenzoxazole) dielectric material.
